(19) United States
(12) Patent Application Publication
(10) Pub. No.: US 2012/0164376 A1
(43) Pub. Date: Jun. 28, 2012

(54) METHOD OF MODIFYING A SUBSTRATE FOR PASSAGE HOLE FORMATION THEREIN, AND RELATED ARTICLES

(75) Inventors: Ronald Scott Bunker, Waterford, NY (US); Bin Wei, Rexford, NY (US); Huan Qi, Beijing (CN)

(73) Assignee: GENERAL ELECTRIC COMPANY, Schenectady, NY (US)

(21) Appl. No.: 12/977,554

(22) Filed: Dec. 23, 2010

(51) Int. Cl. B32B 3/24; B23K 26/00; C23C 14/18

(52) U.S. Cl. 428/131; 427/597; 219/121.71

(57) ABSTRACT

A method for the formation of at least one passage hole in a high-temperature substrate is described. For each desired passage hole or group of passage holes, a node is first formed on the exterior surface of the substrate, by a laser consolidation process. The node functions as a pre-selected entry region for each passage hole. The passage hole can then be formed through the node, into the substrate. Related articles, such as turbine engine components, are also described.

### BACKGROUND

The general subject matter of this invention relates to high-temperature substrates, such as turbine engine components, and more specifically, to methods for incorporating cooling holes into those components.

A gas turbine engine includes a compressor, in which engine air is pressurized. The engine also includes a combustor, in which the pressurized air is mixed with fuel, to generate hot combustion gases. In one typical design (e.g., for aircraft engines), energy is extracted from the gases in a high pressure turbine (HPT) which powers the compressor, and in a low pressure turbine (LPT). The low pressure turbine powers a fan in a turbofan aircraft engine application. In a stationary power application, the HPT and LPT are usually on one shaft that powers a compressor and drives a generator.

The need for cooling systems in gas turbine engines is critical, since the engines usually operate in extremely hot environments. For example, the engine components are often exposed to hot gases having temperatures up to about 3800° F. (2093° C.), for aircraft applications, and up to about 2700° F. (1482° C.), for the stationary power generation applications. To cool the components exposed to the hot gases, these “hot gas path” components typically have both internal convection and external film cooling.

In the case of film cooling, a number of passage holes, i.e., cooling holes in this instance, may extend from a relatively cool surface of the component to a “hot” surface of the component. The cooling holes are usually cylindrical bores which are inclined at a shallow angle, through the metal walls of the component. Film cooling is an important mechanism for temperature control, since it decreases incident heat flux from hot gases to the surfaces of components. A number of techniques may be used to form the cooling holes; depending on various factors, e.g., the necessary depth and shape of the hole. Laser drilling, abrasive liquid (e.g., water) jet cutting, and electrical discharge machining (EDM) are techniques frequently used for forming film cooling holes. The film cooling holes are typically arranged in rows of closely-spaced holes, which collectively provide a large-area cooling blanket over the external surface.

The coolant air is typically compressed air that is bled off the compressor, which is then bypassed around the engine's combustion zone, and fed through the cooling holes to the hot surface. The coolant forms a protective “film” between the hot component surface and the hot gas flow, thereby helping protect the component from heating. Furthermore, walls of the hot gas path components are often covered with a thermal barrier coating (TBC) system, which provides thermal insulation. TBC systems usually include at least one ceramic overcoat, and an underlying metallic bond coat. The benefits of thermal barrier coating systems are well-known.

Exemplary film cooling holes are described in U.S. Pat. No. 7,328,580 (C. P. Lee et al). The patent describes superalloy-based turbine engine parts that contain a pattern of precisely-configured holes terminating at an outside surface of the component. Specific chevron or delta shapes are provided to the hole. For example, the exit regions of such holes may include a center ridge; situated laterally between two “wing troughs”. Joined together, these features form a structure that can provide maximum diffusion of the pressurized cooling air being discharged from an underlying inlet bore of the hole. In some cases, this may lead to a substantial increase in film cooling coverage along critical portions of the component's exterior surface. Of the techniques mentioned above, EDM processes are often preferred for ensuring the optimum, precise configuration for the exit region of the hole.

There are some limitations involved in using EDM. For example, the process cannot be used to form passage holes through an electrically non-conductive ceramic material like a TBC. Thus, the ceramic coating would have to be applied after the passage hole is formed through the substrate. However, coating deposition at that time can involve other drawbacks—especially in relatively large parts. For example, coatings deposited by thermal spray techniques can sometimes severely “coat down” an open passage hole; and can even block the hole passageway. In some cases, this problem can be addressed by purposefully making the passage hole larger, to account for some coating blockage. However, attaining an ideal shape and size for the passage hole by this technique can be very difficult. Moreover, drilling holes through TBC coatings can sometimes damage the coating, by way of undesirable cracks or delamination.

Other processes that can be used in the formation of passage holes do not require a metallic workpiece. Examples include laser techniques and water jet-abrasive systems. Thus, this type of equipment can be used to form passage holes through ceramic coatings, metallic bond coats, and the substrate, at the same time. These techniques may be useful in some situations. However, for other situations, they lack the capability for very precise passage hole shapes—especially in the exit region of the holes, closest to the surface of the part.

With these considerations in mind, new methods directed to the formation of passage holes in high-temperature substrates would be welcome in the art. In the case of turbine engine components, the methods should enable one to form film cooling holes with very precise shapes, to allow for maximum cooling effectiveness during operation of the engine. More specifically, the new methods should be flexible enough to allow for the use of a wide variety of hole-forming techniques, including those that rely on an electrically conductive substrate, like EDM. Methods which minimize or eliminate the possibility of protective coating defects in the vicinity of the passage hole would also be of considerable interest.

### BRIEF DESCRIPTION OF THE INVENTION

One embodiment of this invention is directed to a method for the formation of at least one passage hole in a high-temperature substrate, comprising the following steps:

a) for each passage hole or for a group of passage holes, forming a node on the exterior surface of the substrate by a laser consolidation process; wherein the node comprises an upper surface; and is positioned as a pre-selected entry region for the passage hole, or for the group of passage holes;

b) applying a protective coating system over the exterior surface of the substrate; wherein the coating system comprises at least one underlying metallic layer and one overlying ceramic layer;

c) forming the passage hole or a group of passage holes through each node and into the substrate; while the upper surface of the node is substantially free of the coating system.

Another embodiment is directed to a substrate, having an external surface that can be exposed to high temperatures; and an internal surface, generally opposite the external surface, that can be exposed to lower temperatures; wherein at least one passage hole extends through the substrate, from the external surface to the internal surface; and wherein at least one metallic node is disposed on the external surface of the substrate, and is positioned as an entry region for a passage hole.

### BRIEF DESCRIPTION OF THE DRAWINGS

FIG. 1 is an exemplary, schematic depiction of a laser consolidation system used in embodiments of this invention.

FIG. 2 is an illustration of one exemplary laser consolidation pattern for the formation of a node on a substrate.

FIG. 3 is a photograph of spherical-type nodes deposited on a substrate.

FIG. 4 is a schematic cross-section of an exemplary substrate, having a node applied on its surface.

FIG. 5 is a schematic cross-section of an exemplary substrate and a deposited node, wherein a protective coating is applied over the substrate surface and over the node.

FIG. 6 is a schematic cross-section of the exemplary substrate of FIG. 5, wherein the protective coating has been removed from the surface of the node.

FIG. 7 is a schematic cross-section of a beveled node, deposited on a substrate.

FIG. 8 is a schematic cross-section of the substrate of FIG. 6, in which a passage hole has been formed through the node and through the substrate.

### DETAILED DESCRIPTION OF THE INVENTION

The numerical ranges disclosed herein are inclusive and combinable (e.g., ranges of “up to about 25 wt %”, or, more specifically, “about 5 wt % to about 20 wt %”, are inclusive of the endpoints and all intermediate values of the ranges). In terms of any compositional ranges, weight levels are provided on the basis of the weight of the entire composition, unless otherwise specified; and ratios are also provided on a weight basis. Moreover, the term “combination” is inclusive of blends, mixtures, alloys, reaction products, and the like.

Furthermore, the terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The modifier “about” used in connection with a quantity is inclusive of the stated value, and has the meaning dictated by context, (e.g., includes the degree of error associated with measurement of the particular quantity).

Moreover, in this specification, the suffix “(s)” is usually intended to include both the singular and the plural of the term that it modifies, thereby including one or more of that term (e.g., “the passage hole” may include one or more passage holes, unless otherwise specified). Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described inventive features may be combined in any suitable manner in the various embodiments.

Any substrate that is exposed to high temperatures and requires cooling can be used for this invention. Very often, the substrate is at least one wall of a gas turbine engine component, as noted above. This type of wall, and the turbine components themselves, are described in many references. Non-limiting examples include U.S. Pat. Nos. 6,234,755 (Bunker et al) and 7,328,580 ((Lee et al; hereinafter “Lee”), both of which are incorporated herein by reference. The Lee reference comprehensively describes an aviation gas turbine engine that is axisymmetrical about a longitudinal or axial centerline axis. The engine includes, in ordered flow communication, a fan, a multistage axial compressor, and an annular combustor, which is followed in turn by a high pressure turbine (HPT) and a low pressure turbine (LPT).

As mentioned above, rows or other patterns of passage holes (film cooling holes in most gas turbine applications) need to be formed in many sections of a high-temperature substrate. Those skilled in the art will be able to readily determine the proper location of the holes. For a selected location of each passage hole or group of passage holes, a node is formed on the exterior surface of the substrate. As used herein, the term “node” is meant to describe a wide variety of built-up regions, protuberances, mounds, or “islands”. They may be in a variety of shapes, e.g., square, rectangular, or circular (e.g., a boss). Moreover, the shape of the node may be quite irregular in some cases.

The height of the node is usually a dimension that is less than or equal to the thickness of the coatings (in total thickness) which are to be applied over the exterior surface of the substrate. The node should have lateral dimensions, i.e., the “X” and “Y” dimensions across the horizontal plane of the substrate, that are sufficient to enclose the projected passage hole, regardless of its angle or “pitch”. As also described below, the node can sometimes be in the shape of an elongate rail or berm, serving as the individual entry region for a number of passage holes.

The node is usually (though not always) formed of a composition similar to that of the substrate, or at least metallurgically compatible with the substrate. In general, when the substrate is formed from a superalloy material, the node comprises a high-temperature, metallic material. Other factors which influence the choice of a particular node material include the particular laser deposition process used to form the node; the ability of the node material to form a relatively strong bond with the substrate; and the ability to effectively form passage holes through the node material. In the case of a superalloy substrate, the node is often itself formed of a superalloy material, i.e., one based on nickel, cobalt, or iron.

In most embodiments, the node is formed on the exterior surface of the substrate by a laser consolidation process. Such a process is known in the art, and described in many references. The process is often referred to as “laser cladding”, “laser welding”, “laser engineered net shaping”, and the like. Non-limiting examples of the process are provided in the following U.S. patents and published applications, which are incorporated herein by reference: U.S. Pat. No. 6,429,402 (Dixon et al.); U.S. Pat. No. 6,269,540 (Islam et al); U.S. Pat. No. 5,043,548 (Whitney et al.); U.S. Pat. No. 5,038,014 (Pratt et al); U.S. Pat. No. 4,730,093 (Mehta et al.); U.S. Pat. No. 4,724,299 (Hammeke); U.S. Pat. No. 4,323,756 (Brown et al.); U.S. Patent Publication 2007/0003416 (Bewlay et al); and 2008/0135530 (Lee et al).

FIG. 1 provides a general depiction of one laser consolidation system 10. Formation of a desired article, e.g., the node 12, is taking place on the exterior surface 14, of substrate 16. Laser beam 18 is focused on a selected region of the substrate, according to conventional laser parameters described below. The feed material (deposition material) 20 is delivered from powder source 22, usually by way of a suitable carrier gas 24. The feed material is usually directed to a region on the substrate that is very close to the point where the energy beam intersects substrate surface 14. Melt pool 26 is formed at this intersection, and solidifies to form a “clad track” 12, which in this case, is in the form of the node. As further described below, multiple clad tracks can be deposited next to each other, and/or on top of each other, to complete the desired shape of the node. Typically, as the deposition apparatus is incremented upwardly, the node progresses toward completion in 3-dimensional form. (Other relevant details can be found in Publications 2007/0003416 and 2008/0135530, mentioned above).

A wide variety of lasers can be used in the system of FIG. 1, provided they have a power output sufficient to accomplish the melting function discussed herein. Carbon dioxide lasers operating within a power range of about 0.1 kw to about 30 kw are typically used, although this range can vary considerably. Non-limiting examples of other types of lasers which are suitable for this invention are Nd:YAG lasers, fiber lasers, diode lasers, lamp-pumped solid state lasers, diode-pumped solid state lasers, and excimer lasers. These lasers are commercially available; and those skilled in the art are very familiar with their operation. The lasers can be operated in either a pulsed mode or a continuous mode. As described in Publication 2007/0003416, the laser energy should be sufficient to melt a pool of the material (i.e., the node-forming material here), generally coincident with a “beam spot” at the substrate surface. Usually, the laser energy is applied with a power density in the range of about 10³ to about 10⁷ watts per square centimeter.

The deposition of the feed material forming the node can be carried out under computerized motion control. As mentioned below, one or more computer processors can be used to control the movement of the laser, the feed material stream, and the substrate. More specifically, those skilled in the art of computer-aided design (e.g., CAD-CAM) understand that the desired node can initially be characterized in shape from drawings, or from an article previously formed by conventional methods, such as casting, machining, and the like. Once the shape of the node is numerically characterized, the movement of the part (or equivalently, the deposition head) is programmed for the laser consolidation apparatus, using available numerical control computer programs. These programs create a pattern of instructions as to the movement of the part during each “pass” of the deposition implement, and its lateral displacement between passes. The resulting node reproduces the shape of the numerical characterization quite accurately, even for complex shapes.

Other details regarding laser consolidation equipment and processes are provided in the references set forth above (e.g., U.S. 2007/0003416). Exemplary details and optional features include other techniques for building layers upon previously-formed layers; powder delivery angles used in deposition; the use of multiple feed nozzles for the powder material; and mechanical details for moving the substrate or laser apparatus, relative to each other. As an example, the substrate can be supported on a movable support system, capable of movement in “X, Y, and Z” directions. The support platform could be part of a complex, multi-axis computer numerically controlled (CNC) machine. These machines are known in the art and commercially-available. The use of such a machine to manipulate a substrate is described in U.S. Pat. No. 7,351,290 (Rutkowski et al), incorporated herein by reference. As described in Ser. No. 10/622,063, the use of such a machine allows movement of the substrate along one or more rotational axes, relative to linear axes X and Y. As an example, a conventional rotary spindle could be used to provide rotational movement. Those skilled in the art can use this information to effectively apply nodes to a high-temperature substrate, according to very precise requirements for size, shape, and location. Moreover, those familiar with laser consolidation understand that, in some instances, one or more feed wires of the desired node material may be used in place of the powder-form of the material.

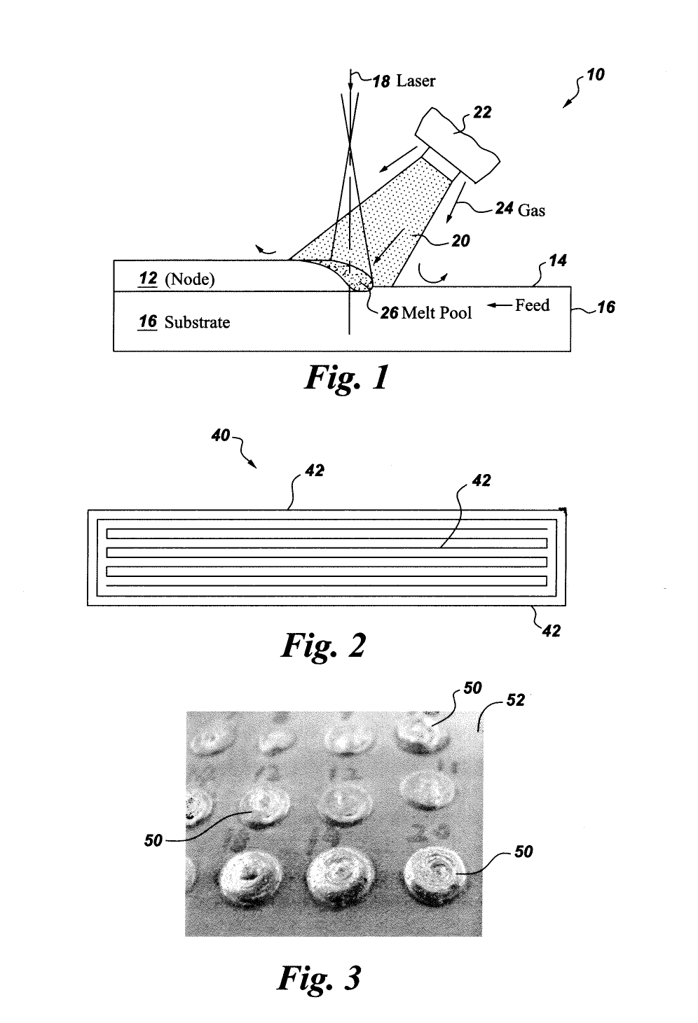

FIG. 2 is an illustration of one technique for the formation of a node, using laser consolidation. In this illustration, the node 40 is prepared by laser-depositing a number of layers of the node material 42, beginning at a selected starting point The laser head is usually moved back and forth, according to a “stitching” pattern; and the speed of the laser is adjusted, according to the location of the particular layer. (In this exemplary illustration, the stitched pattern is surrounded by an outer perimeter layer). Those skilled in the art understand that factors and characteristics like layer thickness, alloy composition, and laser power are often considered together, in determining the most appropriate laser speed. In general, it is desirable to reduce the overall time required for complete deposition, while still obtaining a metallurgically-complete bond with the substrate. Ideally, minimal voids, inclusions, and porosity would result, and there would also be, at most, minimal microstructural changes to the substrate.

As described previously, with each pass of the laser beam, a portion of the previously-deposited material (i.e., an adjacent, parallel layer 42 in FIG. 2) is melted, resulting in a welded bond between the layers. Thus, all of the layers 42 eventually consolidate into a single mass, having a very uniform shape and height. In this figure, node 40 is elongate, and can function as a “rail” over a span of regions intended for passage holes, and discussed below.

In FIG. 3, the laser consolidation technique is used to form nodes 50 in the shape of a “boss” or button. The laser beam (not shown; but associated with a powder-delivery device via computerized control, as discussed above), is directed in a winding spiral at selected regions on the substrate surface 52. The beam can be programmed to deposit the material (e.g., a nickel-based superalloy) in a spiral that winds “inwardly” toward a central point, or outwardly, i.e., starting from a central point. In a manner analogous to the node of FIG. 2, the layers which form each concentric ring of the spiral consolidate into a single mass, having a desired shape and size. In this instance, the shape is a partial sphere. As described herein, each node 50 can be positioned as a pre-selected entry region for a passage hole.

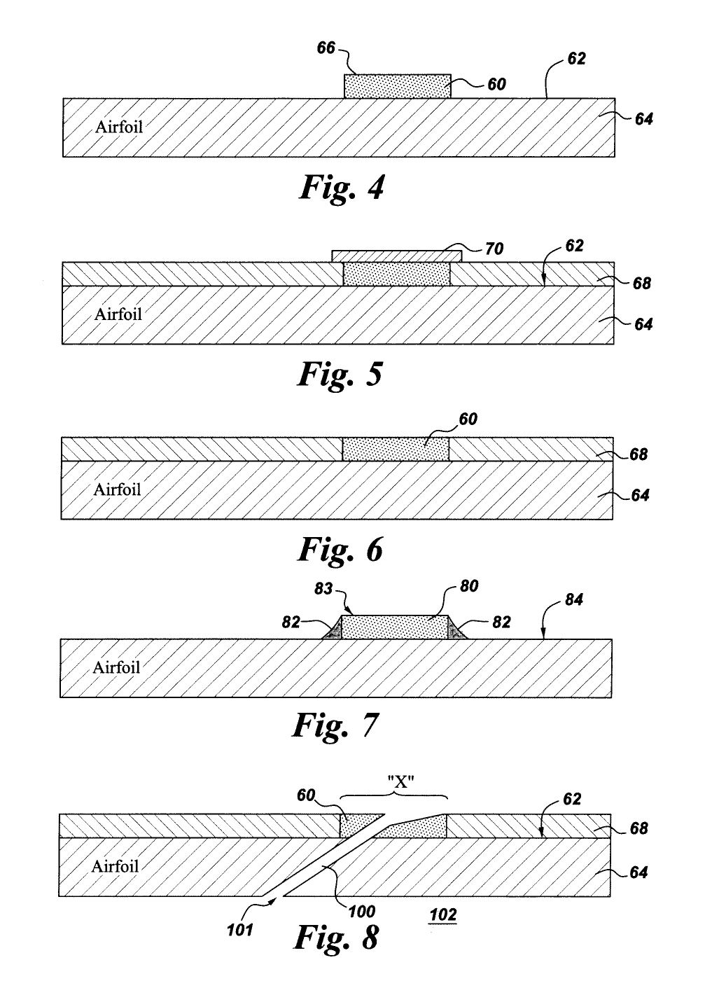

FIGS. 4-6 and 8 describe one illustrative scheme for the formation of passage holes, using the techniques described herein. A node 60 is formed on the exterior surface 62 of a substrate 64, e.g., a turbine airfoil (or any other type of high-temperature substrate), by the laser consolidation process described above. It should be understood that FIG. 4 is a cross-sectional depiction, and node 60 may therefore have a 3-dimensional shape that extends considerably in a direction perpendicular to the depicted surface of the substrate. For example, the node may be formed to serve as multiple, pre-selected entry sites, each for a separate passage hole, along any span of a turbine airfoil. The upper surface 66 of the node is shown as being relatively flat, although other surface profiles are possible.

According to one embodiment, a protective coating system 68 can then be applied over the exterior surface 62 of the substrate, as shown in FIG. 5. A variety of materials can be used for coating system 68. In one embodiment, one or more metallic coatings can be employed. Non-limiting examples of such metallic coatings include metal aluminides, such as nickel aluminide (NiAl) or platinum aluminide (PtAl). Other examples include compositions of the formula MCrAl(X), where “M” is an element selected from the group consisting of Fe, Co and Ni and combinations thereof; and “X” is yttrium, tantalum, silicon, hafnium, titanium, zirconium, boron, carbon, or combinations thereof. Other suitable metallic coatings (including other types of “MCrAl(X)” compositions) are also described in the referenced application Ser. No. 12/953,177; and in U.S. Pat. Nos. 5,626,462 (Jackson et al) and 6,511,762 (Lee et al), which are incorporated herein by reference. Superalloy materials (Ni-, Co-, or Fe-based) can also sometimes be used.

The metallic coating layer can be applied by a variety of techniques. Non-limiting examples include physical vapor deposition (PVD) processes such as electron beam (EB), ion-plasma deposition, or sputtering. Thermal spray processes may also be used, such as air plasma spray (APS), low pressure plasma spray (LPPS), high velocity oxyfuel (HVOF) spray, or high velocity air fuel spraying (HVAF). In some cases, ion plasma deposition is particularly suitable, e.g., a cathodic arc ion plasma deposition, as described in U.S. Published Patent Application No. 2008/0138529, Weaver et al, published Jun. 12, 2008, which is incorporated herein by reference.

As alluded to previously, a ceramic coating is often applied over the metallic coating, or over multiple metallic coatings. This is especially the case for various turbine engine parts. (In these instances, the underlying metallic coating often functions in part as a bond layer). The ceramic coating is usually in the form of a thermal barrier coating (TBC), and can comprise a variety of ceramic oxides, such as zirconia (ZrO₂); yttria (Y₂O₃); and magnesia (MgO). In a preferred embodiment, the TBC comprises yttria-stabilized zirconia (YSZ). Such a composition forms a strong bond with the underlying metallic layer; and provides a relatively high degree of thermal protection to the substrate. (U.S. Pat. No. 6,511,762 provides a description of some aspects of TBC coating systems).

The TBC can be applied by a number of techniques. Choice of a particular technique will depend on various factors, such as the coating composition; its desired thickness; the composition of the underlying metallic layer(s); the region on which the coating is being applied; and the shape of the component. Non-limiting examples of suitable coating techniques include PVD and plasma spray techniques. In some instances, it is desirable for the TBC to have a degree of porosity. As an example, a porous YSZ structure can be formed, using PVD or plasma spray techniques.

The thickness of the TBC will depend on a variety of factors; e.g., its composition; and the thermal environment in which the component will operate. Usually (though not always), TBC's employed for land-based turbine engines will have an overall thickness in the range of about 0.2 mm to about 1 mm. Usually (though not always), TBC's employed for aviation applications, e.g., jet engines, will have an overall thickness in the range of about 0.1 mm to about 0.5 mm.

As described previously, the node is often in the form of an elongate rail or berm, covering the future site of a number of passage holes. In some instances, if the holes are sufficiently close together, there may be no need for any TBC material along the length of the rail, and between the general entry sites of the holes. For example, the cumulative effect of the closely-spaced holes may provide a sufficient degree of coolant air-protection, without any protective coating. A very general guideline can be provided for a planned set of holes, each having an average diameter “D”. In that instance, if the center-to-center spacing between the holes along a linear span is less than about (3×D), no TBC material should be needed along that span. Conversely, if the spacing is greater than about (3×D), individual nodes (i.e., “island patches”) would probably be preferred, while retaining TBC material between the planned passage holes. Routine evaluation or modelling of thermal exposure and film coolant properties can be undertaken to determine what type of node formation and TBC deposition is most appropriate for a given situation.

It is usually important that the upper surface of the node (surface 66 in FIG. 4) is substantially free of any coating materials, prior to the formation of the passage holes through the node, as discussed below. Thus, in one embodiment, a mask (not shown) is positioned over surface 66, prior to any coating step. In general, the mask can comprise any type of material that substantially or completely covers the surface of the node; and that can withstand the conditions of any subsequent coating process.

A number of conventional masks and masking techniques can be employed; some are described in U.S. Pat. No. 7,422,771 (Pietraszkiewicz et al). (Some of the masks are known as “shadowing masks”). As a non-limiting example, the mask could comprise a metal sheet, e.g., an aluminum sheet, aluminum tape, aluminum foil, nickel alloy sheet, or combinations comprising at least one of the foregoing. Aluminum foil is sometimes ideal, due to its low cost, resiliency and effectiveness.

The mask can be applied directly on the surface of the node, or can be positioned (e.g., suspended) over the surface, i.e., blocking the “path” between the source of the coating material and the surface of the node. Moreover, while some types of masks can be removed after coating deposition is complete, other masks can remain on the node surface, during formation of the passage hole. In some instances, the remnants of the mask would be removed from the node surface after the passage holes are complete. It should be clarified that in FIG. 5, coating portion 70, deposited on top of the node, would not be present if a mask had been used.

In other embodiments, a mask is not necessary. Thus, with reference to FIG. 5, coating portion 70 (usually including an underlying metallic coating and an overlying ceramic layer) is deposited on node surface 66, as well as on the rest of substrate surface 62. In this instance, coating portion 70—at least its ceramic portion—is removed (FIG. 6), prior to hole formation, by various techniques. Examples include grinding, polishing, etching, grit-blasting, abrasive water-jet treating; laser ablation; and combinations of such techniques. Those skilled in the art will be able to select the most appropriate technique(s) that will remove substantially all of the coating portion 70, without damaging any other portion of the surrounding coating system 68. As illustrated in FIG. 6, node 60, free of any coating system on top, is surrounded by coating 68, in other locations. The node will function as the entry region for the passage holes, as discussed below.

In some embodiments, the lateral faces (sides) of the nodes are beveled or slanted. As depicted in FIG. 7, node 80 includes side-edges 82, which are slanted, relative to substrate surface 84 and node surface 83. The degree of beveling is illustrated at about 45°, but may vary considerably. It will depend in part on the particular laser consolidation system that has been employed. The beveled edges may be advantageous in some situations. For example, when a masking process is used before coating deposition, the inverse-shape of the bevel, i.e., in an upward direction from the substrate, may be complementary to the coating pattern formed at the edges of the mask.

With reference to FIG. 8, the passage holes 100 are formed through substrate 64, beginning at node/entry region 60. As shown in this cross-sectional configuration, the dimension “X” must be wide enough to accommodate the length of the passage hole 100 passing through the node. The angle of the passage hole, relative to substrate surface 62, can vary greatly, as those skilled in the art understand. In the case of turbine engine airfoils, the particular angle will depend in large part on the specific location of the passage hole on the airfoil; the predicted thermal environment of the airfoil; and the cooling configuration within the airfoil. The referenced U.S. Pat. No. 7,328,580 (Lee et al) provides some general information and details regarding specialized passage holes, i.e., chevron film cooling holes. These film cooling holes usually include a cylindrical inlet bore 101 that extends (downwardly) to an interior region 102 of the component. As mentioned previously, the opposite end of the hole i.e., closest to surface 62, sometimes terminates in a pair of wing troughs having a common ridge between them (not specifically shown in these figures).

The passage holes may be formed by a variety of techniques. Non-limiting examples include abrasive liquid jet cutting; laser machining, electric discharge machining (EDM), electron beam drilling, plunge electrochemical machining, CNC machining, and combinations thereof. Those skilled in the art are familiar with details regarding each type of technique. In some embodiments, EDM techniques are of considerable interest, because of the precise configuration they can provide to sections of a passage hole, as noted above. Various details regarding EDM processes are provided in the Lee reference noted above; e.g., a non-limiting illustration of an EDM electrode, designed specifically to form a complex chevron-hole shape.

As alluded to previously, the use of the nodes provides several important advantages when forming passage holes. For example, the need for a thermal barrier coating (TBC) within the entry region for the passage hole has been generally eliminated. (In the case of a high-temperature airfoil, that entry region appears to be adequately protected by the surrounding flow of cooling air, as well as by the convective cooling inside the passage hole). Moreover, the presence of the metallic node provides excellent processing flexibility. As an example, standard techniques listed above, like laser machining and liquid jet cutting, can form the holes through the metallic node, while specialized techniques like EDM can alternatively be used for some of the high-precision passage holes.

As noted above, high-temperature substrates, on which the nodes are disposed over passage holes, represent another embodiment of the invention. The substrates—protected by protective coating systems—are typically turbine engine components, e.g., airfoils for gas turbines. The passage holes are usually film cooling holes, serving as conduits in the cooling systems needed for extremely hot environments.

In the preceding description, various aspects of the claimed subject matter have been described. For purposes of explanation, specific numbers, systems and/or configurations were set forth to provide a thorough understanding of the claimed subject matter. However, it should be apparent to one skilled in the art, having the benefit of this disclosure, that the claimed subject matter may be practiced without the specific details. In other instances, well-known features were sometimes omitted and/or simplified, so as not to obscure the claimed subject matter. While certain features have been illustrated and/or described herein, many modifications, substitutions, changes and/or equivalents will now occur to those skilled in the art. It is, therefore, to be understood that the appended claims are intended to cover all such modifications and/or changes, as fall within the true spirit of the claimed subject matter. All of the referenced articles, publications, and patents are incorporated herein by reference.

What is claimed:

1. A method for the formation of at least one passage hole in a high-temperature substrate, comprising the following steps:
a) for each passage hole or for a group of passage holes, forming a node on the exterior surface of the substrate by a laser consolidation process; wherein the node comprises an upper surface; and is positioned as a pre-selected entry region for the passage hole, or for the group of passage holes;
b) applying a protective coating system over the exterior surface of the substrate; wherein the coating system comprises at least one underlying metallic layer and one overlying ceramic layer; and
c) forming the passage hole or a group of passage holes through each node and into the substrate; while the upper surface of the node is substantially free of the coating system.

2. The method of claim 1, wherein the entry region has a selected width, relative to a width-dimension of the substrate; that is sufficient to accommodate the length of the passage hole passing through the node.

3. The method of claim 1, wherein the node has a height that is less than or equal to the thickness of the protective coating system disposed on the substrate surface.

4. The method of claim 1, wherein the substrate comprises a superalloy material; and the node comprises a metallic material.

5. The method of claim 4, wherein the metallic material of the node is a superalloy material.

6. The method of claim 1, wherein the laser consolidation process for forming the node comprises melting a metallic material with a laser beam, and depositing the molten material to form a first layer in a desired pattern; and then melting additional metallic material to form successive layers proximate to the first layer, so that the sum of the layers is sufficient to constitute the desired shape of the node.

7. The method of claim 6, wherein the metallic material of the node is in the form of a powder.

8. The method of claim 7, wherein the metallic powder being used to form each layer of the node is directed to a laser beam spot at a particular, selected location on the substrate surface, through at least one delivery nozzle.

9. The method of claim 6, wherein the metallic material of the node is in the form of at least one feed wire.

10. The method of claim 6, wherein the steps of melting the metallic material that forms the node, and depositing it in a desired pattern, are controlled by at least one computer processor.

11. The method of claim 6, wherein at least some of the layers forming the node are deposited adjacent to each other.

12. The method of claim 6, wherein, during each step of melting the metallic node material and depositing the molten material proximate to a previously-deposited layer of material, a portion of the previously-deposited material is melted, so as to form a welded bond between the layers.

13. The method of claim 6, wherein the node is formed by depositing a continuous layer of the molten material in a winding spiral on the substrate surface.

14. The method of claim 1, wherein at least one mask is positioned on or over the upper surface of each node, prior to step (b), so that the node remains substantially free of the coating system material.

15. The method of claim 1, wherein the protective coating system is applied on the substrate surface and on the upper surface of the node; and the coating system is removed from the node surface, prior to step (c).

16. The method of claim 15, wherein removal of the coating system from the upper surface of the node is carried out by at least one technique selected from the group consisting of grinding, polishing, etching, grit-blasting, abrasive water-jet treating; and laser ablation.

17. The method of claim 1, wherein each passage hole in step (c) is formed by a technique selected from the group consisting of abrasive liquid jet cutting; laser machining, electric discharge machining (EDM), electron beam drilling, plunge electrochemical machining, CNC machining, and combinations thereof.

18. The method of claim 1, wherein each passage hole in step (c) is formed by an electric discharge machining (EDM) technique.

19. The method of claim 1,
wherein the metallic layer of the protective coating is formed of a superalloy material; a metal aluminide, or a material having the formula MCrAl(X), wherein M is iron, cobalt, nickel, or combinations thereof; and X is yttrium, tantalum, silicon, hafnium, titanium, zirconium, boron, carbon, or combinations thereof; and
wherein the ceramic layer is formed of a material selected from the group consisting of zirconia (ZrO₂); yttria (Y₂O₃); magnesia (MgO), and combinations thereof.

20. The method of claim 1, wherein the high-temperature substrate is a portion of a turbine engine component.

21. A substrate, having an external surface that can be exposed to high temperatures; and an internal surface generally opposite the external surface, that can be exposed to lower temperatures; wherein at least one passage hole extends through the substrate, from the external surface to the internal surface; and wherein at least one metallic node is disposed on the external surface of the substrate, and is positioned as an entry region for a passage hole.

22. The substrate of claim 21, wherein the external surface of the substrate is covered by a protective coating that substantially surrounds each node, but does not cover any of the nodes.

23. The substrate of claim 22, wherein the node has a height that is less than or equal to the thickness of the surrounding protective coating.

24. The substrate of claim 22, wherein the protective coating comprises at least one underlying metallic layer, and one overlying ceramic layer.

25. The substrate of claim 21, in the form of a turbine engine component.
